(19) United States
(12) Patent Application Publication
(10) Pub. No.: US 2022/0302107 A1
(43) Pub. Date: Sep. 22, 2022

(54) COMPOUND SEMICONDUCTOR AND COMPLEMENTARY METAL OXIDE SEMICONDUCTOR (CMOS) TRANSISTOR INTEGRATION

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 17/206,950

(22) Filed: Mar. 19, 2021

(51) Int. Cl. H01L 27/06; H01L 49/02; H01L 29/20; H01L 29/16; H01L 29/04; H01L 29/778; H01L 23/66; H01L 29/66; H01L 21/8258

(52) U.S. Cl. CPC H01L 27/0605; H01L 27/0629; H01L 28/10; H01L 28/60; H01L 29/2003; H01L 29/16; H01L 29/045; H01L 29/7786; H01L 23/66; H01L 29/66462; H01L 21/8258

(57) ABSTRACT

A radio frequency integrated circuit (RFIC) includes a bulk semiconductor substrate. The RFIC also includes a compound semiconductor field effect transistor (FET). The compound semiconductor FET is composed of a gallium nitride (GaN) epitaxial stack in a trench in the bulk semiconductor substrate having sidewall spacers. The sidewall spacers are between the GaN epitaxial stack and sidewalls of the trench. A carbonized surface layer is at a base of the trench and coupled to the GaN epitaxial stack. The RFIC further includes a complementary metal oxide semiconductor (CMOS) transistor integrated with the compound semiconductor FET on the bulk semiconductor substrate.

### BACKGROUND

### Field

The present disclosure relates generally to wireless communication systems and, more specifically, to a compound semiconductor field effect transistor (FET) and a complementary metal oxide semiconductor (CMOS) transistor integration.

### Background

A wireless device (e.g., a cellular phone or a smartphone) in a wireless communications system may include a radio frequency (RF) transceiver to transmit and receive data for two-way communication. A mobile RF transceiver may include a transmit section for data transmission and a receive section for data reception. The transmit section may include one or more circuits for amplifying and transmitting a communication signal. The amplifier circuits may include amplifier stages that may have driver stages and power amplifier stages. Each of the amplifier stages includes transistors configured to amplify the communication signal. The transistors are selected to operate at substantially higher frequencies for supporting communication enhancements, such as fifth generation (5G) new radio (NR). These transistors are commonly implemented using compound semiconductor transistors, such as high-electron-mobility transistors (HEMTs).

Design challenges for mobile RF front-end (RFFE) modules include performance considerations for meeting future 5G NR transmission frequency specifications. High-electron-mobility transistors are excellent candidates for meeting future 5G NR transmission frequency specifications. Compound semiconductor (e.g., gallium nitride GaN) transistors are mostly used in 5G sub-6 GHz base station power amplifiers. Unfortunately, conventional integration of compound semiconductor field effect transistors (e.g., GaN HEMTs) and planar complementary metal oxide semiconductor (CMOS) transistors is impractical on bulk silicon. CMOS's specification for a (100) orientation for carrier mobility, and GaN's specification for a (111) orientation for reduced zed lattice mismatch are incompatible. A solution for integrating compound semiconductor transistors and CMOS transistors is desired.

### SUMMARY

A radio frequency integrated circuit (RFIC) includes a bulk semiconductor substrate. The RFIC also includes a compound semiconductor field effect transistor (FET). The compound semiconductor FET is composed of a gallium nitride (GaN) epitaxial stack in a trench in the bulk semiconductor substrate having sidewall spacers. The sidewall spacers are between the GaN epitaxial stack and sidewalls of the trench. A carbonized surface layer is at a base of the trench and coupled to the GaN epitaxial stack. The RFIC further includes a complementary metal oxide semiconductor (CMOS) transistor integrated with the compound semiconductor FET on the bulk semiconductor substrate.

A method of making a radio frequency integrated circuit (RFIC) integrating different transistors on a bulk semiconductor substrate is described. The method includes depositing a spacer material on sidewalls of a trench in the bulk semiconductor substrate to form sidewall spacers. The method also includes forming a gallium nitride (GaN) epitaxial stack in the trench in the bulk semiconductor substrate having the sidewall spacers. The sidewall spacers are between the GaN epitaxial stack and the sidewalls of the trench on a carbonized surface layer at a base of the trench to form a compound semiconductor field effect transistor (FET). The method further includes fabricating a complementary metal oxide semiconductor (CMOS) transistor integrated with the compound semiconductor FET on the bulk semiconductor substrate.

A radio frequency front-end (RFFE) module is described. The RFFE module includes a bulk semiconductor substrate. The RFFE module also includes a radio frequency (RF) power amplifier. The RF power amplifier is composed of a compound semiconductor field effect transistor (FET) having a gallium nitride (GaN) epitaxial stack in a trench in the bulk semiconductor substrate having sidewall spacers. The sidewall spacers are between the GaN epitaxial stack and sidewalls of the trench and a carbonized surface layer at a base of the trench coupled to the GaN epitaxial stack. The RFFE module further includes a beamforming (BF) component. The BF component is composed of a complementary metal oxide semiconductor (CMOS) transistor integrated with the compound semiconductor FET on the bulk semiconductor substrate.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates a perspective view of a semiconductor wafer.

FIG. 2 illustrates a cross-sectional view of a die.

FIG. 3 shows a block diagram of a wireless device.

FIG. 4 illustrates a radio frequency integrated circuit (RFIC) having a planar complementary metal oxide semiconductor (CMOS) transistor integrated with a high-electron-mobility transistor (HEMT) on a bulk semiconductor substrate, according to aspects of the present disclosure.

FIGS. 5A-5J illustrate formation of the radio frequency integrated circuit (RFIC) of FIG. 4, integrating different transistor types on a bulk semiconductor substrate, according to aspects of the present disclosure.

FIG. 6 is a flow diagram illustrating a method of making a radio frequency integrated circuit (RFIC) integrating different transistor types on a bulk semiconductor substrate, in accordance with aspects of the present disclosure.

FIG. 7 is a block diagram showing an exemplary wireless communications system, in which an aspect of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Fabrication of mobile radio frequency (RF) chips (e.g., mobile RF transceivers) becomes complex due to cost and power consumption considerations. A mobile RF transceiver may include a transmit section for data transmission and a receive section for data reception. The transmit section of the mobile RF transceiver includes circuits for amplifying and transmitting the communication signal. The amplifier circuits may include amplifier stages that may have driver stages and power amplifier stages, including transistors configured to amplify the communication signal. The transistors configured to amplify the communication signal are selected to operate at substantially higher frequencies for supporting communication enhancements, such as 5G new radio (NR). These transistors are commonly implemented using compound semiconductor transistors, such as high-electron-mobility transistors (HEMTs).

A high-electron-mobility transistor (HEMT) is a type of field effect transistor (FET) that relies on a junction between different semiconductor materials with different bandgaps to form a heterojunction. A high-electron-mobility transistor may also use a III-V compound semiconductor material, a II-VI compound semiconductor material, or other like compound semiconductor material. High-electron-mobility transistors may improve upon heterojunction transistors by supporting substantially higher transmission frequencies, which may meet 5G NR performance specifications. A gallium nitride (GaN) high-electron-mobility transistor (HEMT) is used within a power amplifier of a mobile platform device. The increased transmission frequency supported by gallium nitride high-electron-mobility transistors is generally used for base station applications rather than mobile platform devices.

Successful fabrication of modern semiconductor chip products, such as compound semiconductor bipolar transistors and field effect transistors involves interplay between the materials and the processes employed. The process flow for semiconductor fabrication of the integrated circuit structure may include front-end-of-line (FEOL) processes, middle-of-line (MOL) (also referred to as middle-end-of-line (MEOL)) processes, and back-end-of-line (BEOL) processes to form interconnects (e.g., M1, M2, M3, M4, etc.) The front-end-of-line processes may include the set of process steps that form the active devices, such as transistors, capacitors, and diodes.

The front-end-of-line processes include ion implantation, anneals, oxidation, chemical vapor deposition (CVD) or atomic layer deposition (ALD), etching, chemical mechanical polishing (CMP), and epitaxy. The middle-of-line processes may include the set of process steps that enable connection of the transistors to back-end-of-line interconnects. These steps include silicidation and contact formation as well as stress introduction. The back-end-of-line processes may include the set of process steps that form the interconnects that tie the independent transistors and form circuits.

Design challenges for mobile radio frequency front-end (RFFE) modules and beamforming chips include a reduced form factor due a decreased antenna tile size (e.g., relative to 1/λ²) for supporting sub-6 GHz and millimeter wave frequencies. Compound semiconductor (e.g., gallium nitride GaN) high-electron-mobility transistors (HEMTs) are mostly used in 5G sub-6 GHz base station RF power amplifiers. By contrast, planar complementary metal oxide semiconductor (CMOS) transistors are used in beamforming chips. Integration of GaN HEMTs and planar CMOS transistors is desired to meet form factor considerations due to the noted, decreased antenna tile size to meet 5G NR performance specifications. Unfortunately, conventional integration of compound semiconductor field effect transistors (e.g., GaN HEMTs) and planar complementary metal oxide semiconductor (CMOS) transistors is impractical on bulk silicon. CMOS's specification for a (100) orientation for carrier mobility, and GaN's specification for a (111) orientation for reduced zed lattice mismatch are incompatible. A solution for integrating compound semiconductor transistors and CMOS transistors is desired.

Aspects of the present disclosure are directed to a high-electron-mobility transistor (HEMT) and a complementary metal oxide semiconductor (CMOS) transistor integration. In one aspect of the present disclosure, a radio frequency integrated circuit (RFIC) includes a bulk semiconductor substrate. The RFIC also includes a high-electron-mobility transistor. In this aspect of the present disclosure, the HEMT is composed of a gallium nitride (GaN) epitaxial stack in a trench in the bulk semiconductor substrate. In some aspects of the present disclosure, the trench includes oxide sidewall spacers between the GaN epitaxial stack and sidewalls of the trench. In this aspect of the present disclosure, the trench also includes a carbonized surface at a base of the trench coupled to the GaN epitaxial stack. The RFIC also includes a planar CMOS transistor integrated with the HEMT on the bulk semiconductor layer.

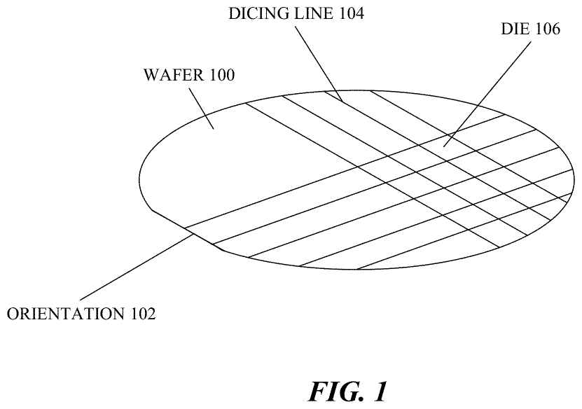

FIG. 1 illustrates a perspective view of a semiconductor wafer. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be composed of a compound semiconductor material, such as gallium arsenide (GaAs), indium phosphide (InP), or gallium nitride (GaN), a ternary material such as indium gallium arsenide (InGaAs), aluminum gallium arsenide (AlGaAs), or indium gallium stibium (InGaSb), quaternary materials such as indium gallium arsenide phosphide (InGaAsP), or any material that can be a substrate material for other compound semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

After the wafer 100 is processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

After the wafer 100 is separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of packaging that provide access to the die 106. The die 106 may also be directly accessed through wire bonding, probes, or other connections without mounting the die 106 into a separate package.

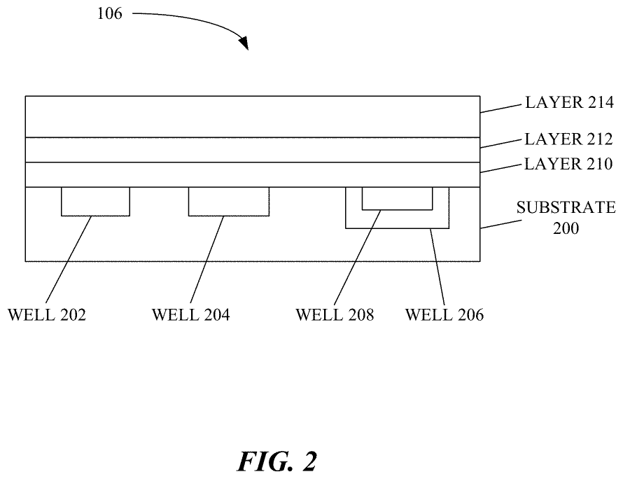

FIG. 2 illustrates a cross-sectional view of a die 106. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200. The semiconductor substrate may also have a well 206 and a well 208. The well 208 may be completely within the well 206, and, in some cases, may form a high-electron-mobility transistor (HEMT), or other like compound semiconductor transistor. The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

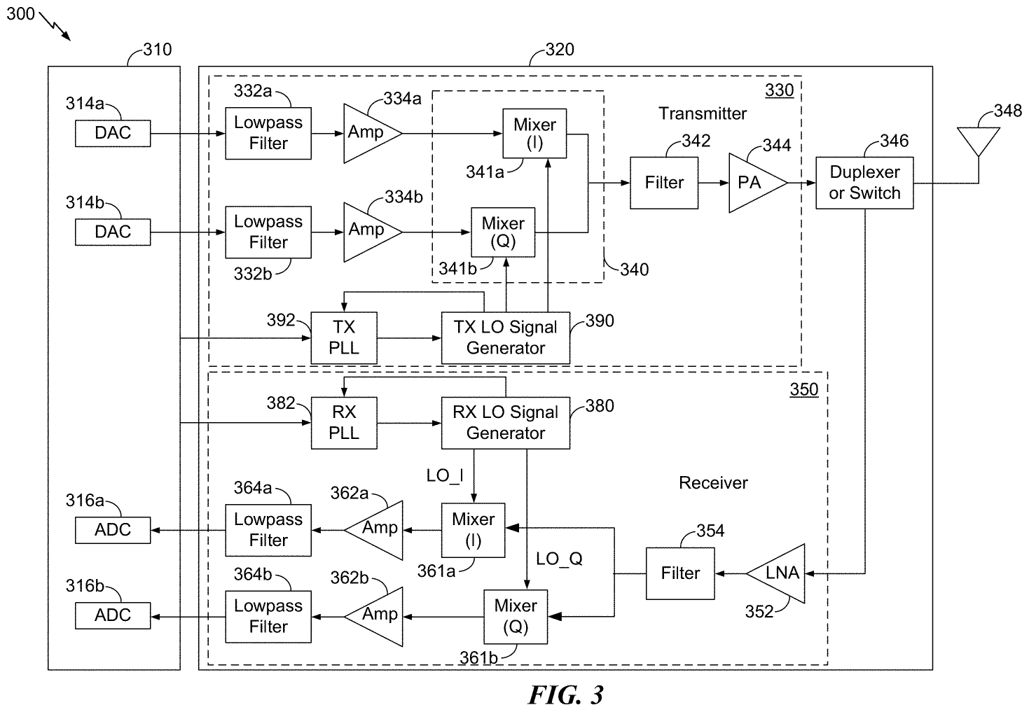

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure. The substrate 200, the wells 202-208, and the layers (e.g., 210-214) may enable formation of high-electron-mobility transistors. High-electron-mobility transistors are often used in high speed circuits, such as radio frequency (RF) chip designs, including RF power amplifiers in mobile RF transceivers of an RF front-end module, for example, as shown in FIG. 3.

FIG. 3 shows a block diagram of an exemplary design of a wireless device 300. FIG. 3 shows an example of a transceiver 320, which may be a wireless transceiver (WTR). In general, the conditioning of the signals in a transmitter 330 and a receiver 350 may be performed by one or more stages of amplifier(s), filter(s), upconverters, downconverters, and the like. These circuit blocks may be arranged differently from the configuration shown in FIG. 3. Furthermore, other circuit blocks not shown in FIG. 3 may also be used to condition the signals in the transmitter 330 and receiver 350. Unless otherwise noted, any signal in FIG. 3, or any other figure in the drawings, may be either single-ended or differential. Some circuit blocks in FIG. 3 may also be omitted.

In the example shown in FIG. 3, the wireless device 300 generally includes the transceiver 320 and a data processor 310. The data processor 310 may include a memory (not shown) to store data and program codes, and may generally include analog and digital processing elements. The transceiver 320 may include the transmitter 330 and receiver 350 that support bi-directional communication. In general, the wireless device 300 may include any number of transmitters and/or receivers for any number of communication systems and frequency bands. All or a portion of the transceiver 320 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages, e.g., from radio frequency to an intermediate frequency (IF) in one stage, and then from intermediate frequency to baseband in another stage for a receiver. In the direct-conversion architecture, a signal is frequency converted between radio frequency and baseband in one stage. The super-heterodyne and direct-conversion architectures may use different circuit blocks and/or have different requirements. In the example shown in FIG. 3, the transmitter 330 and the receiver 350 are implemented with the direct-conversion architecture.

In a transmit path, the data processor 310 processes data to be transmitted. The data processor 310 also provides in-phase (I) and quadrature (Q) analog output signals to the transmitter 330 in the transmit path. In an exemplary aspect, the data processor 310 includes digital-to-analog-converters (DACs) 314a and 314b for converting digital signals generated by the data processor 310 into the in-phase (I) and quadrature (Q) analog output signals (e.g., I and Q output currents) for further processing.

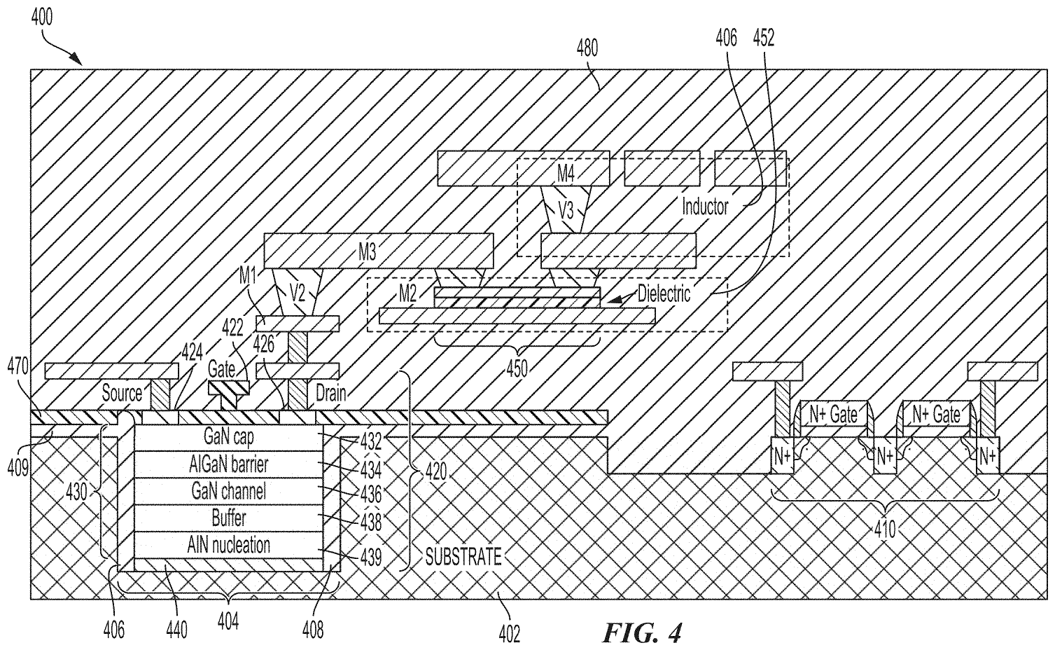

Within the transmitter 330, lowpass filters 332a and 332b filter the in-phase (I) and quadrature (Q) analog transmit signals, respectively, to remove undesired images caused by the prior digital-to-analog conversion. Amplifiers (Amp) 334a and 334b amplify the signals from lowpass filters 332a and 332b, respectively, and provide in-phase (I) and quadrature (Q) baseband signals. An upconverter 340 upconverts the in-phase (I) and quadrature (Q) baseband signals with in-phase (I) and quadrature (Q) transmit (TX) local oscillator (LO) signals from a TX LO signal generator 390 to provide an upconverted signal. A filter 342 filters the upconverted signal to remove undesired images caused by the frequency upconversion as well as noise in a receive frequency band. A power amplifier (PA) 344 amplifies the signal from the filter 342 to obtain the desired output power level and provides a transmit radio frequency signal. The power amplifier 344 may be implemented using a high-electron-mobility transistor (HEMT), such as a compound semiconductor field effect transistor (FET) having a self-aligned gate, for example, as shown in FIG. 4. The transmit radio frequency signal is routed through a duplexer/switch 346 and transmitted via an antenna 348.

In a receive path, the antenna 348 receives communication signals and provides a received radio frequency (RF) signal, which is routed through the duplexer/switch 346 and provided to a low noise amplifier (LNA) 352. The duplexer/switch 346 is designed to operate with a specific receive (RX) to transmit (TX) (RX-to-TX) duplexer frequency separation, such that RX signals are isolated from TX signals. The received RF signal is amplified by the LNA 352 and filtered by a filter 354 to obtain a desired RF input signal. Downconversion mixers 361a and 361b mix the output of the filter 354 with in-phase (I) and quadrature (Q) receive (RX) LO signals (i.e., LO_I and LO_Q) from an RX LO signal generator 380 to generate in-phase (I) and quadrature (Q) baseband signals. The in-phase (I) and quadrature (Q) baseband signals are amplified by amplifiers 362a and 362b and further filtered by lowpass filters 364a and 364b to obtain in-phase (I) and quadrature (Q) analog input signals, which are provided to the data processor 310. In the exemplary configuration shown, the data processor 310 includes analog-to-digital-converters (ADCs) 316a and 316b for converting the analog input signals into digital signals for further processing by the data processor 310.

In FIG. 3, the transmit local oscillator (TX LO) signal generator 390 generates the in-phase (I) and quadrature (Q) TX LO signals used for frequency upconversion, while a receive local oscillator (RX LO) signal generator 380 generates the in-phase (I) and quadrature (Q) RX LO signals used for frequency downconversion. Each LO signal is a periodic signal with a particular fundamental frequency. A phase locked loop (PLL) 392 receives timing information from the data processor 310 and generates a control signal used to adjust the frequency and/or phase of the TX LO signals from the TX LO signal generator 390. Similarly, a PLL 382 receives timing information from the data processor 310 and generates a control signal used to adjust the frequency and/or phase of the RX LO signals from the RX LO signal generator 380.

A power amplifier (PA) 344 may be implemented using a high-electron-mobility transistor (HEMT). A high-electron-mobility transistor is a type of field effect transistor (FET) that relies on a junction between different semiconductor materials with different bandgaps to form a heterojunction, similar to a heterojunction bipolar transistor. High-electron-mobility transistors improve upon heterojunction transistors by supporting substantially higher transmission frequencies, which meet 5G NR transmission specifications.

Design challenges for mobile radio frequency front-end (RFFE) modules and beamforming chips include a reduced form factor due to a decreased antenna tile size (e.g., relative to 1/λ²) for supporting sub-6 GHz and millimeter wave frequencies. Compound semiconductor (e.g., gallium nitride (GaN)) high-electron-mobility transistors (HEMTs) are mostly used in 5G sub-6 GHz base station RF power amplifiers. By contrast, planar complementary metal oxide semiconductor (CMOS) transistors are used in beamforming chips Integration of GaN HEMTs and planar CMOS transistors is desired to meet form factor considerations due to the noted, decreased antenna tile size to meet 5G NR performance specifications. Unfortunately, conventional integration of compound semiconductor field effect transistors (e.g., GaN HEMTs) and planar complementary metal oxide semiconductor (CMOS) transistors is impractical on bulk silicon. CMOS's specification for a (100) orientation for carrier mobility, and GaN's specification for a (111) orientation for reduced zed lattice mismatch are incompatible. A solution for integrating compound semiconductor transistors and CMOS transistors is shown in FIG. 4.

FIG. 4 illustrates a radio frequency integrated circuit (RFIC) having a planar complementary metal oxide semiconductor (CMOS) transistor integrated with a high-electron-mobility transistor (HEMT) on a bulk semiconductor substrate, according to aspects of the present disclosure. As shown in FIG. 4, an RFIC 400 includes a bulk semiconductor substrate 402. The RFIC 400 includes a planar complementary metal oxide semiconductor (CMOS) transistor 410 on the bulk semiconductor substrate 402. The planar CMOS transistor 410 may be configured to implement a beamforming (BF) component of the RFIC 400. The RFIC 400 also includes a high-electron-mobility transistor (HEMT) 420 on the bulk semiconductor substrate 402. The HEMT 420 may implement an RF power amplifier of the RFIC 400.

In this aspect of the present disclosure, the HEMT 420 includes a compound semiconductor layer composed of a gallium nitride (GaN) epitaxial stack 430 in a trench 404 in the bulk semiconductor substrate 402. In some aspects, the trench 404 includes oxide sidewall spacers 406, 408, between the GaN epitaxial stack 430 and sidewalls of the trench 404. In this example, the trench 404 includes a carbonized layer 440 at a base of the trench 404, and the carbonized layer 440 is coupled to the GaN epitaxial stack 430. The RFIC 400 integrates the planar complementary metal oxide semiconductor (CMOS) transistor 410 on the bulk semiconductor substrate 402. The planar CMOS transistor 410 may be formed as shown in FIGS. 1 and 2. The bulk semiconductor substrate 402 may be a three hundred (300) millimeter (mm) thick bulk silicon substrate having a [100] crystal orientation (e.g., a [100] crystal structure), which provides a substantial reduction in substrate cost.

The HEMT 420 is shown in a T-gate configuration. Representatively, the RFIC 400 includes a trench 404 formed in the bulk semiconductor substrate 402 (e.g., bulk silicon (Si). In aspects of the present disclosure, a carbonized layer 440 is formed at a base of the trench 404 to enable preparation of the GaN epitaxial stack 430 of the HEMT 420. In this example, the GaN epitaxial stack 430 includes a nucleation layer 439 (e.g., aluminum nitride (AlN)) on the carbonized layer 440. A buffer layer 438 is on the nucleation layer 439. The buffer layer 438, which may be composed of a compound semiconductor material (e.g., graded aluminum gallium nitride (AlGaN)), is grown on the nucleation layer 439 to isolate defects from the bulk semiconductor substrate 402. The buffer layer 438 mitigates the lattice mismatch between the epitaxial layers and the substrate, enabling more pristine growth of the active layers of the HEMT 420.

The HEMT 420 also includes a channel 436, which is generally grown after the buffer layer 438 and may be composed of gallium nitride (GaN), or other like compound semiconductor materials. Ideally, electron conduction of the HEMT 420 should take place in the channel 436. A barrier layer 434 (e.g., aluminum gallium nitride (AlGaN)) is grown on the channel 436. In addition, a cap layer 432 (e.g., GaN) is grown on the barrier layer 434. Additional details for forming the cap layer 432, the barrier layer 434, the channel 436, the buffer layer 438, and the nucleation layer 439 are omitted to avoid obscuring innovative details of the present disclosure.

In aspects of the present disclosure, the trench 404 is formed with oxide sidewall spacers 406, 408 (e.g., SiO₂) for isolation and protection against carbonization. The oxide sidewall spacers 406, 408 and the carbonized layer 440 enable selective epitaxy of gallium nitride (GaN) layers to form the GaN epitaxial stack 430 of the high-electron-mobility transistor (HEMT) 420. The carbonized layer 440 is formed by locally carbonizing a surface of silicon carbide (SiC) to promote pristine growth of the GaN layers of the GaN epitaxial stack 430 of the HEMT 420. In aspects of the present disclosure, a GaN HEMT is integrated inside the trench 404 and patterned on the bulk semiconductor substrate 402 (e.g., the [100] crystal orientation of a silicon (Si) substrate). That is, a selective GaN epitaxy inside the trench 404 is protected by the oxide sidewall spacers 406, 408. In addition, the locally carbonized top layer (e.g. 440) promotes pristine GaN epitaxy due to significant reduction of lattice mismatch (e.g., from 17% to 3%).

The HEMT 420 includes a gate 422, having a base gate and a head gate according to the T-gate configuration shown in FIG. 4. As further illustrated in FIG. 4, a nitride layer 470, on a pad oxide layer 409, surrounds a source ohmic contact layer 424 and a drain ohmic contact layer 426. An interlayer dielectric (ILD) layer 480 and the nitride layer 470 surround the base gate of the gate 422. The interlayer dielectric (ILD) layer 480 surrounds the head gate of the gate 422. Also shown are source/drain trench (CA) contacts to the source/drain ohmic contacts 424/426. For example, the CA drain contact couples the drain ohmic contact layer 426 to a capacitor 450 and an inductor 460 through back-end-of-line (BEOL) metallization layers M1, M2, M3, and M4, and vias V2 and V3. In this example, the capacitor 450 is a metal-insulator-metal (MIM) capacitor composed of a dielectric 452 between an M1 metallization layer and an M2 metallization layer. The inductor 460 is formed from M3 and M4 metallization layers and the V3 via. In some aspects, the inductor 460 and the capacitor 450 are coupled through the BEOL metallization layers M1, M2, M3, and M4, and vias V2 and V3 to form an inductor-capacitor (LC) filter.

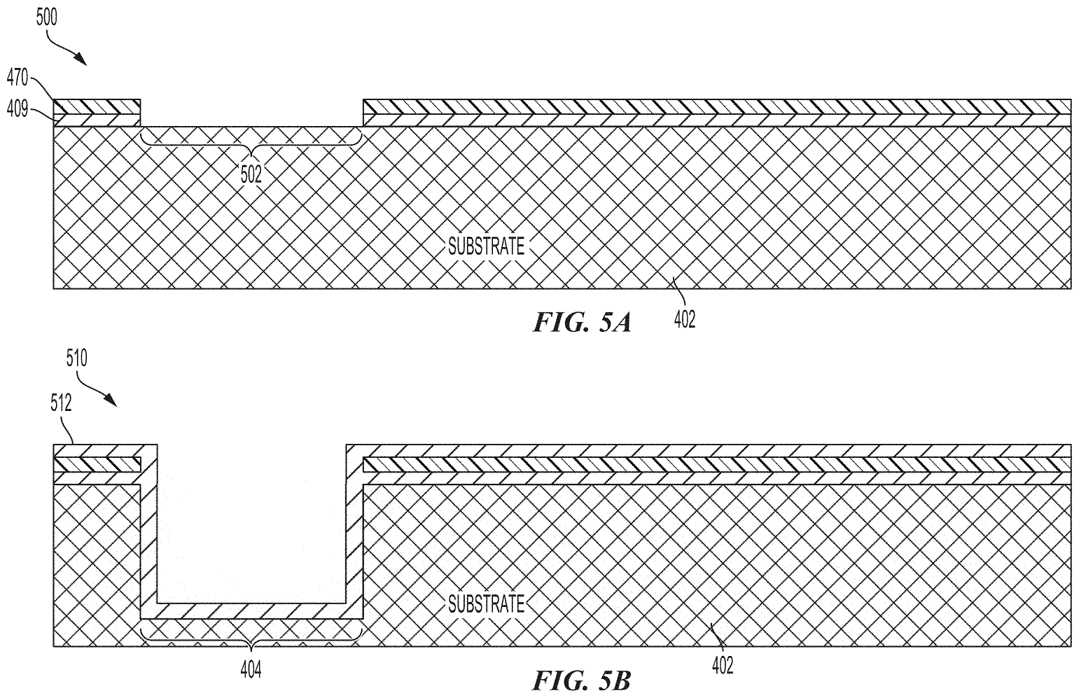

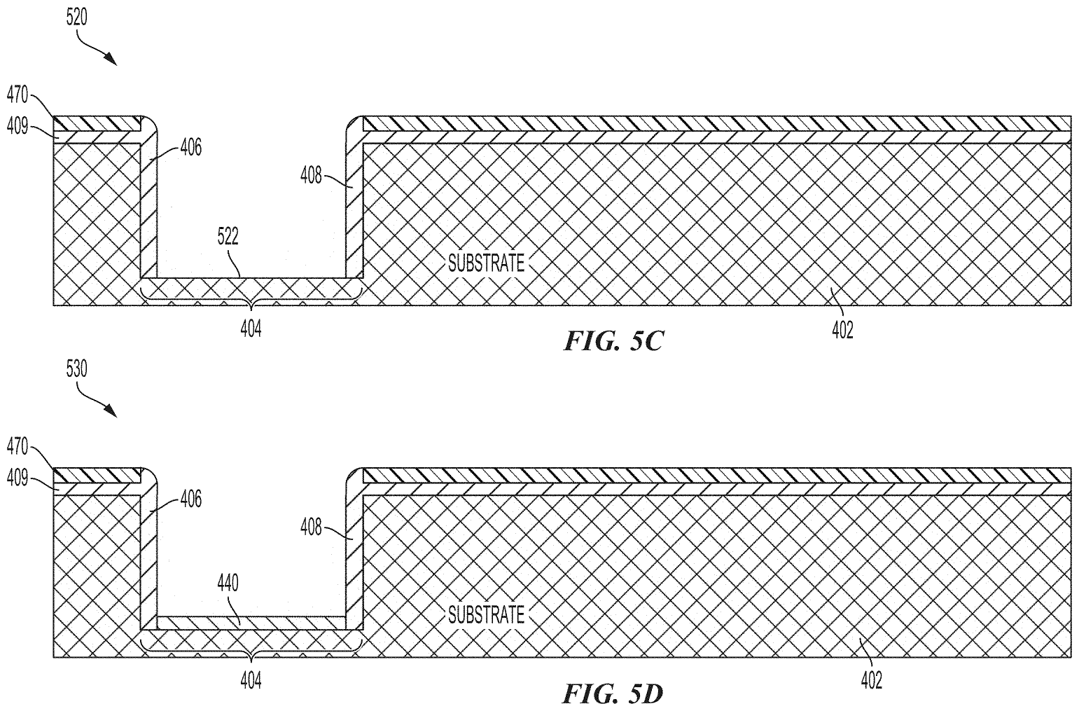

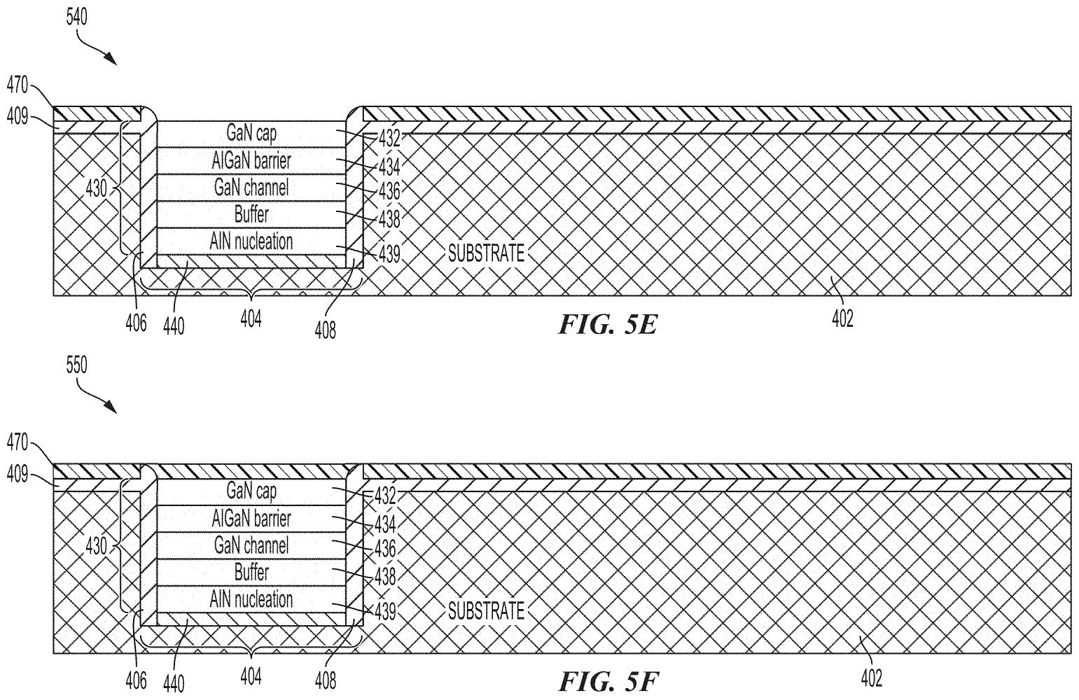

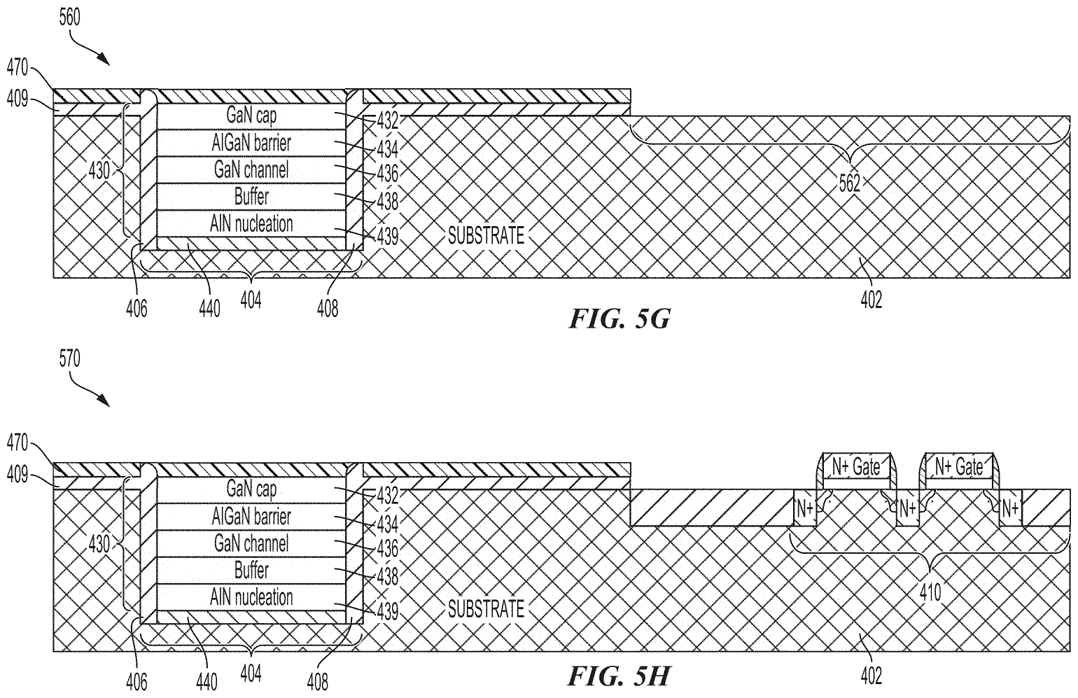

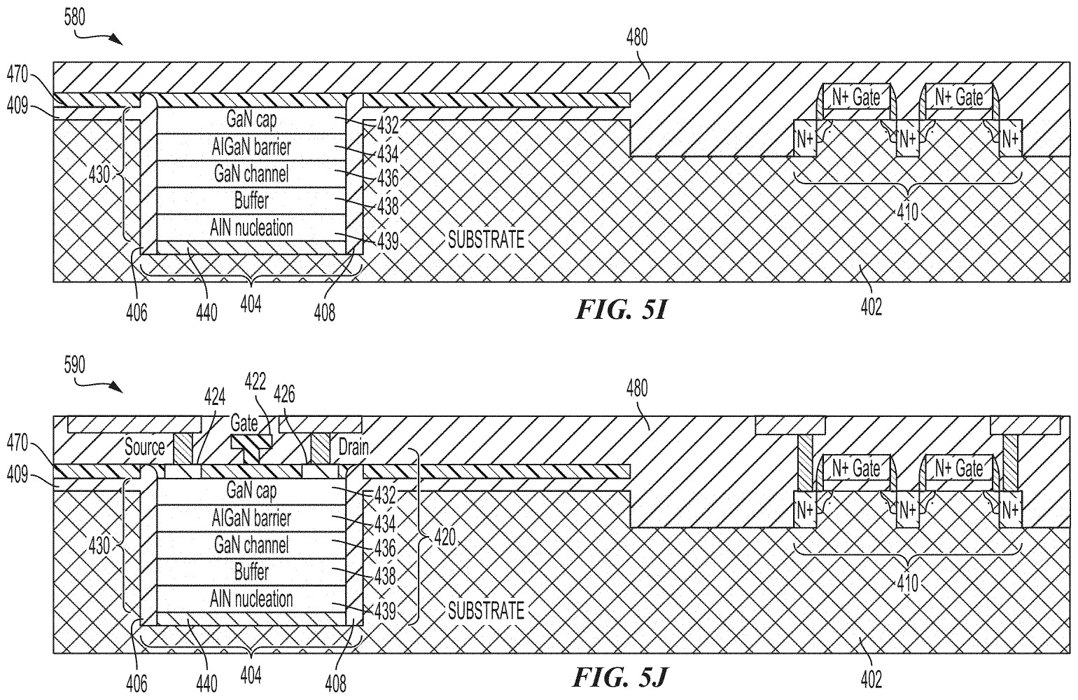

Formation of the RFIC 400 is further illustrated in FIGS. 5A-5J. FIGS. 5A-5J illustrate formation of the RFIC 400 of FIG. 4, integrating different transistor types on a bulk semiconductor substrate, according to aspects of the present disclosure.

FIG. 5A illustrates a portion of the RFIC 400 after step 500 of a transistor integration process, according to aspects of the present disclosure. FIG. 5A shows the bulk semiconductor substrate 402 following deposition of a pad oxide layer 409 (e.g., silicon oxide (SiO₂) or buffer oxide) followed by deposition of the nitride layer 470 on the pad oxide layer 409. In this example, the nitride layer 470 and the pad oxide layer 409 are patterned and etched to expose a surface of the bulk semiconductor substrate 402 through an opening 502.

FIG. 5B illustrates a portion of the RFIC 400 after step 510 of the transistor integration process, according to aspects of the present disclosure. In step 510 of the transistor integration process, the exposed surface of the bulk semiconductor substrate 402 is etched through the opening 502 to form the trench 404. The step 510 further includes a sacrificial oxide etch followed by a liner oxide deposition to line the trench 404 with an oxide layer 512.

FIG. 5C illustrates a portion of the RFIC 400 after step 520 of the transistor integration process to form the oxide sidewall spacers 406, 408, according to aspects of the present disclosure. At step 520, an anisotropic etch of the oxide layer 512 is performed to expose the nitride layer 470 and a base 522 of the trench 404 to complete formation of the oxide sidewall spacers 406, 408. For example, a spacer material (e.g., silicon nitride (SiN), silicon oxide (SiO₂), or silicon carbon nitro-oxide (SiCNO)) is deposited on sidewalls of the trench 404 to form the oxide sidewall spacers 406, 408.

FIG. 5D illustrates a portion of the RFIC 400 after step 530 of the transistor integration process to form the carbonized layer 440, according to aspects of the present disclosure. At step 530, an exposed surface of the bulk semiconductor substrate 402 at the base 522 of the trench 404 is carbonized using a rapid thermal chemical vapor deposition (RTCVD) process to form the carbonized layer 440.

FIG. 5E illustrates a portion of the RFIC 400 after step 540 of the transistor integration process to grow the gallium nitride (GaN) epitaxial stack 430, according to aspects of the present disclosure. At step 540, the buffer layer 438, which may be composed of a compound semiconductor material (e.g., graded aluminum gallium nitride (AlGaN)), is grown on the nucleation layer 439 to isolate defects from the bulk semiconductor substrate 402. The buffer layer 438 mitigates the lattice mismatch between the epitaxial layers and the substrate, enabling more pristine growth of the active layers of the high-electron-mobility transistor (HEMT) 420. In addition, the channel 436 (e.g., a channel layer) is epitaxially grown on the buffer layer 438. The barrier layer 434 is shown on the channel 436, supporting the cap layer 432. The various layers of the GaN epitaxial stack 430 may be epitaxially grown using a metal organic chemical vapor deposition (MOCVD) process.

FIG. 5F illustrates a portion of the RFIC 400 after step 550 of the transistor integration process to deposit the nitride layer 470 on the cap layer 432 and the oxide sidewall spacers 406, 408. The deposition of the nitride layer 470 is followed by a chemical mechanical polish (CMP) process on the nitride layer 470. The CMP process may apply a zirconia or silica-based abrasive to perform a timed/touch CMP process on the nitride layer 470.

FIG. 5G illustrates a portion of the RFIC 400 after step 560 of the transistor integration process to begin formation of the planar complementary metal oxide semiconductor (CMOS) transistor 410, according to aspects of the present disclosure. At step 560, a mask and etch process is performed on the nitride layer 470 and the pad oxide layer 409 to open a window defining a CMOS region 562 of the bulk semiconductor substrate 402 of the RFIC 400.

FIG. 5H illustrates a portion of the RFIC 400 after step 570 of the transistor integration process to form the complementary metal oxide semiconductor (CMOS) transistor 410 within the CMOS region 562, according to aspects of the present disclosure. At step 570, a CMOS process performs shallow trench isolation (STI) formation through silicidation in the CMOS region 562 to form the planar CMOS transistor 410.

FIG. 5I illustrates a portion of the RFIC 400 after step 580 of the transistor integration process to form the interlayer dielectric (ILD) layer 480, according to aspects of the present disclosure. At step 580, the ILD layer 480 is deposited on the HEMT 420 and the planar complementary metal oxide semiconductor (CMOS) transistor 410. Once deposited, the ILD layer 480 is subjected to a touch chemical mechanical planarization (CMP) polishing process.

FIG. 5J illustrates a portion of the RFIC 400 after step 590 of the transistor integration process to form middle-of-line (MOL) contacts to the HEMT 420 and the planar CMOS transistor 410, according to aspects of the present disclosure. In this example, the source ohmic contact layer 424 and the drain ohmic contact layer 426 (e.g., titanium (Ti)/aluminum (Al)/tantalum (Ta)) may be formed using a contact lithography deposition on the cap layer 432. An ohmic anneal process (e.g., at 800° C.) forms the source ohmic contact layer 424 and the drain ohmic contact layer 426.

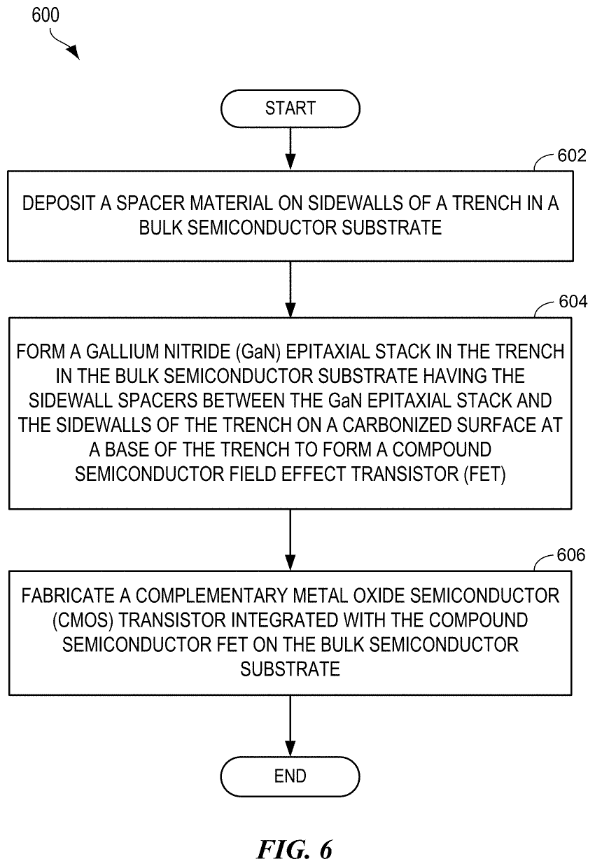

In this example, the source ohmic contact layer 424 and the drain ohmic contact layer 426 are formed in areas of the cap layer 432 not covered by the nitride layer 470. In addition, the gate 422 is also formed with a gate material (e.g., nickel (Ni)/titanium (Ti)/gold (Au)/titanium nitride (TiN)). A material of a head of the gate 422 may be tungsten (W), aluminum (Al), copper (Cu), tantalum (Ta), or other like conductive material. Middle-of-line (MOL) contacts are also formed to the source/drain regions of the planar CMOS transistor 410. Additional details for forming the MOL contacts to the planar CMOS transistor 410 are omitted to avoid obscuring innovative details of the present disclosure. Formation of the back-end-of-line (BEOL) metallization layers to the capacitor 450 and the inductor 460 to complete formation of the RFIC 400 of FIG. 4 may be performed after the transistor integration process shown in FIG. 6.

FIG. 6 is a flow diagram illustrating a method 600 of making a radio frequency integrated circuit (RFIC) integrating different transistors on a bulk semiconductor substrate, in accordance with aspects of the present disclosure. The blocks in the method 600 can be performed in or out of the order shown, and in some aspects, can be performed at least in part in parallel.

The method 600 begins at block 602, where a spacer material is deposited on sidewalls of a trench in a bulk semiconductor substrate. For example, FIG. 5C illustrates the RFIC 400 after step 520 of the transistor integration process to form the oxide sidewall spacers 406, 408, according to aspects of the present disclosure. At step 520, an anisotropic etch of the oxide layer 512 is performed to expose the nitride layer 470 and a base 522 of the trench 404 to complete formation of the oxide sidewall spacers 406, 408. For example, a spacer material (e.g., silicon nitride (SiN), silicon oxide (SiO₂), or silicon carbon nitro-oxide (SiCNO)) is deposited on sidewalls of the trench 404 to form the oxide sidewall spacers 406, 408.

At block 604, an epitaxial stack comprising a gallium nitride (GaN) high electron mobility transistor (HEMT) is formed in the trench in the bulk semiconductor substrate having the sidewall spacers between the epitaxial stack of the GaN HEMT and the sidewalls of the trench. The epitaxial stack of the GaN HEMT is formed on a carbonized surface layer at a base of the trench to form a compound semiconductor field effect transistor (FET). For example, FIG. 5E illustrates the RFIC 400 after step 540 of the transistor integration process to grow the epitaxial stack 430 of the GaN HEMT, according to aspects of the present disclosure. At step 540, the buffer layer 438 is grown on the nucleation layer 439 to isolate defects from the bulk semiconductor substrate 402. In addition, the channel 436 (e.g., a channel layer), is epitaxially grown on the buffer layer 438. The barrier layer 434 is shown on the channel 436, supporting the cap layer 432. The various layers of the GaN epitaxial stack 430 may be epitaxially grown using a metal organic chemical vapor deposition (MOCVD) process.

Referring again to FIG. 6, at block 606, a complementary metal oxide semiconductor (CMOS) transistor is fabricated and integrated with the compound semiconductor FET on the bulk semiconductor substrate. For example, FIG. 5G illustrates the RFIC 400 after step 560 of the transistor integration process to begin formation of the planar CMOS transistor 410. At step 560, a mask and etch process is performed on the nitride layer 470 and the pad oxide layer 409 to open a window defining a CMOS region 562 of the bulk semiconductor substrate 402 of the RFIC 400. In addition, FIG. 5H illustrates the RFIC 400 after step 570 of the transistor integration process to form the planar CMOS transistor 410 within the CMOS region 562. At step 570, a CMOS process performs shallow trench isolation (STI) formation through silicidation in the CMOS region 562 to form the planar CMOS transistor 410.

Aspects of the present disclosure support epitaxial grow of a compound semiconductor (e.g., gallium nitride (GaN) on a bulk semiconductor (e.g., silicon (Si)) substrate having the [100] crystal orientation. In some aspects, a selective GaN epitaxy growth is performed inside a trench of the bulk semiconductor substrate, between sidewall spacers of the trench. In this aspect of the present disclosure, a selective carbonization at a base trench surface forms a carbonized layer to support growth of the compound semiconductor epitaxial stack. Formation of the compound semiconductor epitaxial stack enables co-integration of a high-electron-mobility transistor (HEMT) and a planar complementary metal oxide semiconductor (CMOS) transistor on a bulk silicon substrate, which reduces cost, while providing scalability.

Beneficially, bowing/warping concerns of a radio frequency integrated circuit (RFIC) including the HEMT/CMOS transistor integration is mitigated by (a) a carbonization (SiC layer), and (b) a selective epitaxy (e.g., using sparse gallium nitride (GaN) islands, rather than epitaxy on a full wafer). Furthermore, interconnect parasitics are reduced with this co-integration, which may be important for millimeter waver communications. The co-integration enables a form factor reduction of a radio frequency front-end (RFFE) and a beamforming (BF) component size reduction specified to keep up with antenna area reduction. In addition, a bill of material (BOM) cost is reduced as well as simplification of testing.

According to a further aspect of the present disclosure, a radio frequency integrated circuit (RFIC) includes a compound semiconductor field effect transistor (FET) and planar complementary metal oxide semiconductor (CMOS) transistor integration. The RFIC may include means for supporting the compound semiconductor FET. The supporting means may, for example, include a bulk semiconductor substrate 402, as shown in FIGS. 4 and 5A-5J. In another aspect, the aforementioned means may be any layer, module, or any apparatus configured to perform the functions recited by the aforementioned means.

According to additional aspects of the present disclosure, a compound semiconductor material may include, but is not limited to, gallium nitride (GaN), gallium arsenide (GaAs), indium phosphide (InP), gallium antimonide (GaSb), gallium phosphide (GaP), indium gallium arsenide (InGaAs), aluminum gallium arsenide (AlGaAs), indium gallium phosphide (InGaP), aluminum gallium phosphide (AlGaP), aluminum gallium antimonide (AlGaSb), indium gallium stibium (InGaSb), indium gallium nitride (InGaN), aluminum gallium nitride (AlGaN), indium gallium arsenide phosphide (InGaAsP), indium gallium arsenide antimonide (InGaAsSb), or indium gallium arsenide:nitride (InGaAs:N). These are exemplary only, and other materials are possible.

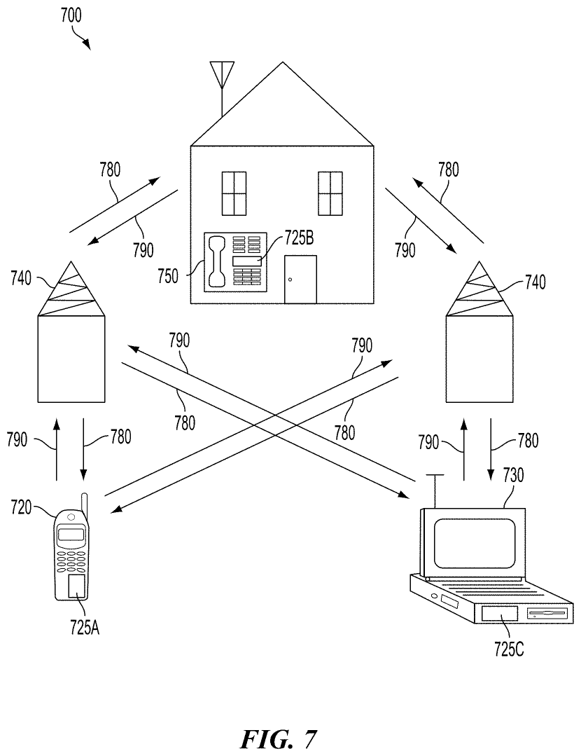

FIG. 7 is a block diagram showing an exemplary wireless communication system 700 in which an aspect of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed compound semiconductor FET and CMOS transistor integration. It will be recognized that other devices may also include the disclosed compound semiconductor FET and CMOS transistor integration, such as the base stations, user equipment, and network equipment. FIG. 7 shows forward link signals 780 from the base station 740 to the remote units 720, 730, and 750 and reverse link signals 790 from the remote units 720, 730, and 750 to base station 740.

In FIG. 7, remote unit 720 is shown as a mobile telephone, remote unit 730 is shown as a portable computer, and remote unit 750 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieves data or computer instructions, or combinations thereof. Although FIG. 7 illustrates remote units according to the aspects of the disclosure, the disclosure is not limited to these exemplary illustrated units. Aspects of the disclosure may be suitably employed in many devices, which include the disclosed compound semiconductor FET and CMOS transistor integration.

Implementation examples are described in the following numbered clauses:

1. A radio frequency integrated circuit (RFIC), comprising:

a bulk semiconductor substrate;

a compound semiconductor field effect transistor (FET) comprising a gallium nitride (GaN) epitaxial stack in a trench in the bulk semiconductor substrate having sidewall spacers between the GaN epitaxial stack and sidewalls of the trench and a carbonized surface layer at a base of the trench coupled to the GaN epitaxial stack; and a complementary metal oxide semiconductor (CMOS) transistor integrated with the compound semiconductor FET on the bulk semiconductor substrate.

2. The RFIC of clause 1, in which the bulk semiconductor substrate comprises a bulk silicon substrate having a [100] crystal orientation.

3. The RFIC of any of clauses 1-2, in which the compound semiconductor FET comprises a GaN high-electron-mobility transistor (HEMT) and the CMOS transistor comprises a planar CMOS transistor.

4. The RFIC of clause 3, in which the GaN HEMT comprises a radio frequency (RF) power amplifier.

5. The RFIC of any of clauses 3-4, in which the planar CMOS transistor comprises a beamforming (BF) component.

6. The RFIC of any of clauses 1-5, in which the carbonized surface layer comprises a silicon carbide (SiC) layer.

7. The RFIC of any of clauses 1-6, further comprising:

a metal-insulator-metal (MIM) capacitor coupled to a drain contact of the compound semiconductor FET; and

an inductor coupled to the MIM capacitor to form an inductor-capacitor (LC) filter.

8. The RFIC of any of clauses 1-7, further comprising:

a pad oxide layer on the bulk semiconductor substrate; and

a nitride layer on the pad oxide layer.

9. The RFIC of any of clauses 1-8, in which the sidewall spacers comprise silicon nitride (SiN), silicon oxide (SiO₂), and/or silicon carbon nitro-oxide (SiCNO).

10. The RFIC of any of clauses 1-9, integrated into a base station.

11. A method of making a radio frequency integrated circuit (RFIC) integrating different transistors on a bulk semiconductor substrate, comprising:

depositing a spacer material on sidewalls of a trench in the bulk semiconductor substrate to form sidewall spacers;

forming a gallium nitride (GaN) epitaxial stack in the trench in the bulk semiconductor substrate having the sidewall spacers between the GaN epitaxial stack and the sidewalls of the trench on a carbonized surface layer at a base of the trench to form a compound semiconductor field effect transistor (FET); and

fabricating a complementary metal oxide semiconductor (CMOS) transistor integrated with the compound semiconductor FET on the bulk semiconductor substrate.

12. The method of clause 11, further comprising:

depositing of a pad oxide layer on a surface of the bulk semiconductor substrate;

depositing a nitride layer on the pad oxide layer; and

patterning and etching the nitride layer and the pad oxide layer to expose the surface of the bulk semiconductor substrate through an opening.

13. The method of clause 12, further comprising:

etching the exposed surface of the bulk semiconductor substrate through the opening to form the trench;

etching a sacrificial oxide; and

depositing a liner oxide to line the trench with an oxide layer.

14. The method of clause 13, further comprising anisotropic etching of the oxide layer to expose the nitride layer and the base of the trench to form the sidewall spacers.

15. The method of clause 14, further comprising carbonizing an exposed surface of the bulk semiconductor substrate at the base of the trench to form the carbonized surface layer.

16. The method of any of clauses 11-15, further comprising:

forming a metal-insulator-metal (MIM) capacitor coupled to a drain contact of the compound semiconductor FET; and

forming an inductor coupled to the MIM capacitor to form an inductor-capacitor (LC) filter.

17. A radio frequency front-end (RFFE) module, comprising:

a bulk semiconductor substrate;

a radio frequency (RF) power amplifier comprising a compound semiconductor field effect transistor (FET) comprising a gallium nitride (GaN) epitaxial stack in a trench in the bulk semiconductor substrate having sidewall spacers between the GaN epitaxial stack and sidewalls of the trench and a carbonized surface layer at a base of the trench coupled to the GaN epitaxial stack; and

a beamforming (BF) component comprising a complementary metal oxide semiconductor (CMOS) transistor integrated with the compound semiconductor FET on the bulk semiconductor substrate.

18. The RFFE module of clause 17, in which the bulk semiconductor substrate comprises a bulk silicon substrate having a [100] crystal orientation.

19. The RFFE module of any of clauses 17-18, in which the compound semiconductor FET comprises a GaN high-electron-mobility transistor (HEMT) and the CMOS transistor comprises a planar CMOS transistor.

20. The RFFE module of any of clauses 17-19, further comprising:

a metal-insulator-metal (MIM) capacitor coupled to a drain contact of the compound semiconductor FET; and

an inductor coupled to the MIM capacitor to form an inductor-capacitor (LC) filter.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communication networks and/or communication technologies. The apparatuses, methods, and systems disclosed herein may also be implemented digitally and differentially, among others. The various components illustrated in the figures may be implemented as, for example, but not limited to, software and/or firmware on a processor, application-specific integrated circuit (ASIC)/field programmable gate arrays (FPGA)/digital signal processor (DSP), or dedicated hardware. Also, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described herein may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, include compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination of set of codes and/or instructions on a non-transitory processor-readable storage medium and/or computer-readable storage medium, which may be incorporated into a computer program product.

Although the present disclosure provides certain example aspects and applications, other aspects that are apparent to those of ordinary skill in the art, including aspects which do not provide all of the features and advantages set forth herein, are also within the scope of this disclosure. For example, the apparatuses, methods, and systems described herein may be performed digitally and differentially, among others. Accordingly, the scope of the present disclosure is intended to be defined only by reference to the appended claims.

What is claimed is:

1. A radio frequency integrated circuit (RFIC), comprising:
a bulk semiconductor substrate;
a compound semiconductor field effect transistor (FET) comprising a gallium nitride (GaN) epitaxial stack in a trench in the bulk semiconductor substrate having sidewall spacers between the GaN epitaxial stack and sidewalls of the trench and a carbonized surface layer at a base of the trench coupled to the GaN epitaxial stack; and
a complementary metal oxide semiconductor (CMOS) transistor integrated with the compound semiconductor FET on the bulk semiconductor substrate.

2. The RFIC of claim 1, in which the bulk semiconductor substrate comprises a bulk silicon substrate having a [100] crystal orientation.

3. The RFIC of claim 1, in which the compound semiconductor FET comprises a GaN high-electron-mobility transistor (HEMT) and the CMOS transistor comprises a planar CMOS transistor.

4. The RFIC of claim 3, in which the GaN HEMT comprises a radio frequency (RF) power amplifier.

5. The RFIC of claim 3, in which the planar CMOS transistor comprises a beamforming (BF) component.

6. The RFIC of claim 1, in which the carbonized surface layer comprises a silicon carbide (SiC) layer.

7. The RFIC of claim 1, further comprising:
a metal-insulator-metal (MIM) capacitor coupled to a drain contact of the compound semiconductor FET; and
an inductor coupled to the MIM capacitor to form an inductor-capacitor (LC) filter.

8. The RFIC of claim 1, further comprising:
a pad oxide layer on the bulk semiconductor substrate; and
a nitride layer on the pad oxide layer.

9. The RFIC of claim 1, in which the sidewall spacers comprise silicon nitride (SiN), silicon oxide (SiO₂), and/or silicon carbon nitro-oxide (SiCNO).

10. The RFIC of claim 1, integrated into a base station.

11. A method of making a radio frequency integrated circuit (RFIC) integrating different transistors on a bulk semiconductor substrate, comprising:
depositing a spacer material on sidewalls of a trench in the bulk semiconductor substrate to form sidewall spacers;
forming a gallium nitride (GaN) epitaxial stack in the trench in the bulk semiconductor substrate having the sidewall spacers between the GaN epitaxial stack and the sidewalls of the trench on a carbonized surface layer at a base of the trench to form a compound semiconductor field effect transistor (FET); and
fabricating a complementary metal oxide semiconductor (CMOS) transistor integrated with the compound semiconductor FET on the bulk semiconductor substrate.

12. The method of claim 11, further comprising:
depositing of a pad oxide layer on a surface of the bulk semiconductor substrate;
depositing a nitride layer on the pad oxide layer; and
patterning and etching the nitride layer and the pad oxide layer to expose the surface of the bulk semiconductor substrate through an opening.

13. The method of claim 12, further comprising:
etching the exposed surface of the bulk semiconductor substrate through the opening to form the trench;
etching a sacrificial oxide; and
depositing a liner oxide to line the trench with an oxide layer.

14. The method of claim 13, further comprising anisotropic etching of the oxide layer to expose the nitride layer and the base of the trench to form the sidewall spacers.

15. The method of claim 14, further comprising carbonizing an exposed surface of the bulk semiconductor substrate at the base of the trench to form the carbonized surface layer.

16. The method of claim 11, further comprising:
forming a metal-insulator-metal (MIM) capacitor coupled to a drain contact of the compound semiconductor FET; and
forming an inductor coupled to the MIM capacitor to form an inductor-capacitor (LC) filter.

17. A radio frequency front-end (RFFE) module, comprising:
a bulk semiconductor substrate;
a radio frequency (RF) power amplifier comprising a compound semiconductor field effect transistor (FET) comprising a gallium nitride (GaN) epitaxial stack in a trench in the bulk semiconductor substrate having sidewall spacers between the GaN epitaxial stack and sidewalls of the trench and a carbonized surface layer at a base of the trench coupled to the GaN epitaxial stack; and
a beamforming (BF) component comprising a complementary metal oxide semiconductor (CMOS) transistor integrated with the compound semiconductor FET on the bulk semiconductor substrate.

18. The RFFE module of claim 17, in which the bulk semiconductor substrate comprises a bulk silicon substrate having a [100] crystal orientation.

19. The RFFE module of claim 17, in which the compound semiconductor FET comprises a GaN high-electron-mobility transistor (HEMT) and the CMOS transistor comprises a planar CMOS transistor.

20. The RFFE module of claim 17, further comprising:
a metal-insulator-metal (MIM) capacitor coupled to a drain contact of the compound semiconductor FET; and
an inductor coupled to the MIM capacitor to form an inductor-capacitor (LC) filter.
